(19) United States
(12) Patent Application Publication
(10) Pub. No.: US 2025/0105792 A1
(43) Pub. Date: Mar. 27, 2025

(54) Load Modulated Radio-frequency Amplifier with Supply Voltage Error Compensation

(71) Applicant: Apple Inc., Cupertino, CA (US)

(72) Inventors: Stephan Henzler, Munich (DE); Andreas Langer, Munich (DE)

(21) Appl. No.: 18/739,614

(22) Filed: Jun. 11, 2024

Related U.S. Application Data
(60) Provisional application No. 63/584,463, filed on Sep. 21, 2023.

(51) Int. Cl. H03F 1/02; H03F 3/24

(52) U.S. Cl. CPC H03F 1/0233; H03F 3/245; H03F 2200/451

(57) ABSTRACT

Wireless circuitry may include a radio-frequency amplifier configured to receive a power supply voltage, a load modulation circuit configured to generate a load control signal, and supply voltage error compensation circuitry configured to generate an error signal that is applied to the load control signal to produce a compensated load control signal. The compensated load control signal can be used to tune an adjustable load component of the radio-frequency amplifier. The power supply voltage may exhibit a piecewise constant waveform. The supply voltage error compensation circuitry can include a reference signal generator configured to generate a reference signal and a filter configured to generate a target signal based on the reference signal. The error signal can be computed based on a difference between the target signal and a sensed or estimated version of the power supply voltage received at the amplifier.

This application claims the benefit of U.S. Provisional Patent Application No. 63/584,463, filed Sep. 21, 2023, which is hereby incorporated by reference herein in its entirety.

### FIELD

This disclosure relates generally to electronic devices and, more particularly, to electronic devices with wireless communications circuitry.

### BACKGROUND

Electronic devices can be provided with wireless communications capabilities. An electronic device with wireless communications capabilities has wireless communications circuitry with one or more antennas. Wireless transceiver circuitry in the wireless communications circuitry uses the antennas to transmit and receive radio-frequency signals.

Radio-frequency signals transmitted by an antenna can be fed through one or more power amplifiers, which are configured to amplify low power analog signals to higher power signals more suitable for transmission through the air over long distances. It can be challenging to design a satisfactory power amplifier for an electronic device.

### SUMMARY

An electronic device may include wireless communications circuitry. The wireless communications circuitry may include one or more processors or signal processing blocks for generating baseband signals, a transceiver for receiving the digital signals and for generating corresponding radio-frequency signals, and one or more radio-frequency power amplifiers configured to amplify the radio-frequency signals for transmission by one or more antennas in the electronic device. At least one of the radio-frequency power amplifiers can be implemented as a load modulated radio-frequency amplifier circuit. The load modulated radio-frequency amplifier circuit can include an amplifier core coupled to an adjustable load impedance. Such type of amplifier circuit can also be referred to as a load-line modulated radio-frequency power amplifier.

As aspect of the disclosure provides wireless circuitry that includes a radio-frequency amplifier configured to receive a radio-frequency signal generated from a baseband signal and to receive a power supply voltage, a load modulation circuit configured to generate a load control signal from the baseband signal, and supply voltage error compensation circuitry configured to generate an error signal that is applied to the load control signal to produce a compensated load control signal, where an adjustable load component of the radio-frequency amplifier is tuned by the compensated load control signal. The wireless circuitry can further include an adaptive power tracking control circuit configured to generate a digital code from the baseband signal and a power management circuit configured to generate the power supply voltage for the radio-frequency amplifier based on the digital code. The digital code generated by the adaptive power tracking control circuit is piecewise constant. The supply voltage error compensation circuitry can include a reference signal generator configured to receive the digital code and to generate a reference supply voltage waveform, a low-pass filter configured to receive the reference supply voltage waveform and to generate a corresponding target supply voltage waveform, and a supply voltage detector configured to sense the power supply voltage received at the radio-frequency amplifier, wherein the supply voltage error compensation circuitry is configured to generate the error signal based on a difference between the sensed power supply voltage and the target supply voltage waveform.

In another embodiment, the supply voltage error compensation circuitry can include a supply voltage estimation block configured to receive the digital code and to generate an estimated power supply signal based on a digital model associated with the power management circuit, a scaling and filtering block configured to receive the digital code and to generate a reference power supply signal by scaling and filtering the received digital code, and a combiner configured to generate the error signal based on a difference between the estimated power supply signal and the reference power supply signal.

An aspect of the disclosure provides a method of operating wireless circuitry that includes: receiving, with a radio-frequency amplifier, a radio-frequency signal generated from a baseband signal and receiving a power supply voltage; generating, with a load modulation circuit, a load control signal from the baseband signal; generating, with supply voltage error compensation circuitry, an error signal and combining the error signal with the load control signal to produce a compensated load control signal; and tuning an adjustable load component of the radio-frequency amplifier with the compensated load control signal. The method can further include: receiving, with an adaptive power tracking controller, the baseband signal and generate a corresponding digital code; and receiving, with a power management circuit, the digital code and driving the power supply voltage that is received at the radio-frequency amplifier. The method can further include generating a reference power supply signal based on the digital code, generating a target power supply signal by filtering the reference power supply signal, and sensing the power supply voltage, where generating the error signal comprises generating the error signal by computing a difference between the sensed power supply voltage and the target power supply signal. The method can alternatively include estimating the power supply voltage based on a digital model of the power management circuit, where generating the error signal comprises generating the error signal by computing a difference between the estimated power supply voltage and the target power supply signal.

An aspect of the disclosure provides circuitry that includes: an amplifier having a data input, a first control input, and a second control input; a first control signal generator configured to output a first control signal to the first control input of the amplifier; a second control signal generator configured to output a second control signal; and error compensation circuitry configured to sense or estimate the first control signal received at the first control input of the amplifier and configured to generate an error signal for compensating the second control signal, where the compensated second control signal is provided to the second control input of the amplifier. The first control signal generator can include a power tracking controller configured to output a digital code and a power management circuit configured to output the first control signal based on the digital code. The amplifier can include an adjustable load that is tuned by the compensated second control signal. The error compensation circuitry can include a reference signal generator configured to generate a reference signal based on the digital code and a filter configured to generate a target signal based on the reference signal, where the error signal is computed based on a difference between the target signal and the sensed or estimated version of the first control signal.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry having amplifiers in accordance with some embodiments.

FIG. 3 is a diagram of illustrative transmit circuitry that includes a load modulated amplifier coupled to supply voltage error compensation circuitry in accordance with some embodiments.

FIG. 4 is a timing diagram of an illustrative adaptive power tracking scheme showing settling transients.

FIG. 5 is a timing diagram showing how a supply voltage error compensation signal can be generated in accordance with some embodiments.

FIG. 6 is a diagram showing illustrative supply voltage error compensation circuitry having a supply reference generator and a filter in accordance with some embodiments.

FIG. 7 is a diagram showing illustrative circuit implementation details within the supply voltage error compensation circuitry shown in FIG. 6 in accordance with some embodiments.

FIG. 8 is a flow chart of illustrative steps for operating the wireless circuitry shown in at least FIGS. 3, 6, and 7 in accordance with some embodiments.

FIG. 9 is a diagram showing illustrative supply voltage error compensation circuitry having a scaling and filtering block and a supply voltage estimator in accordance with some embodiments.

### DETAILED DESCRIPTION

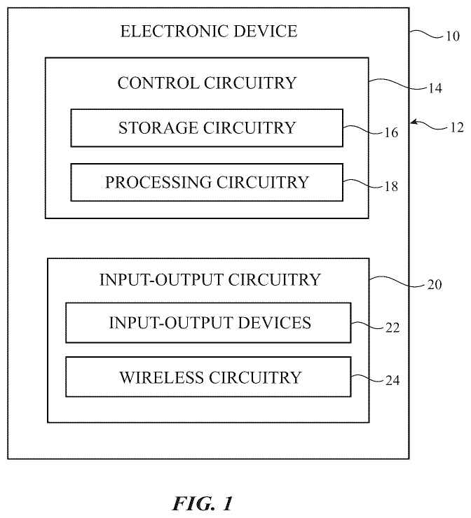

An electronic device such as device 10 of FIG. 1 may be provided with wireless circuitry. The wireless circuitry may include one or more processors for generating a baseband signal that can be conveyed to an antenna through a radio-frequency transmit path. The radio-frequency transmit path can include an upconversion circuit, a radio-frequency power amplifier such as a load modulated amplifier, an adaptive power tracking (APT) controller for adjusting a power supply voltage for the load modulated amplifier, and a load modulation controller for tuning an adjustable load for the load modulated amplifier.

Supply voltage error compensation circuitry is provided that is coupled to the adaptive power tracking controller and that includes a supply voltage detector for detecting or estimating a power supply voltage being received at the load modulated amplifier. The supply voltage error compensation circuitry can generate a reference supply voltage waveform based on a digital signal output from the adaptive power tracking controller, a target supply voltage waveform based on the detected or estimated power supply voltage being received at the load modulated amplifier, and a corresponding error signal based on a difference between the reference supply voltage waveform and the target supply voltage waveform. The error signal output from the supply voltage error compensation circuitry can be used to compensate a load control signal output from the load modulation controller to generate a compensated load control signal. The adjustable load of the load modulated amplifier can then be tuned by the compensated load control signal. Wireless circuitry configured and operated in this way can be technically advantageous and beneficial by allowing for slower power supply voltage settling times without transmit data throughput degradation.

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more microprocessors, microcontrollers, digital signal processors, host processors, baseband processor integrated circuits, application specific integrated circuits, central processing units (CPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols—sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 5G protocols, etc.), antenna diversity protocols, satellite navigation system protocols (e.g., global positioning system (GPS) protocols, global navigation satellite system (GLONASS) protocols, etc.), antenna-based spatial ranging protocols (e.g., radio detection and ranging (RADAR) protocols or other desired range detection protocols for signals conveyed at millimeter and centimeter wave frequencies), or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support wireless communications. Wireless circuitry 24 (sometimes referred to herein as wireless communications circuitry 24) may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s).

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), cellular sidebands, 6G bands between 100-1000 GHz (e.g., sub-THz, THz, or tremendously high frequency bands), other centimeter or millimeter wave frequency bands between 10-300 GHz, near-field communications frequency bands (e.g., at 13.56 MHz), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest.

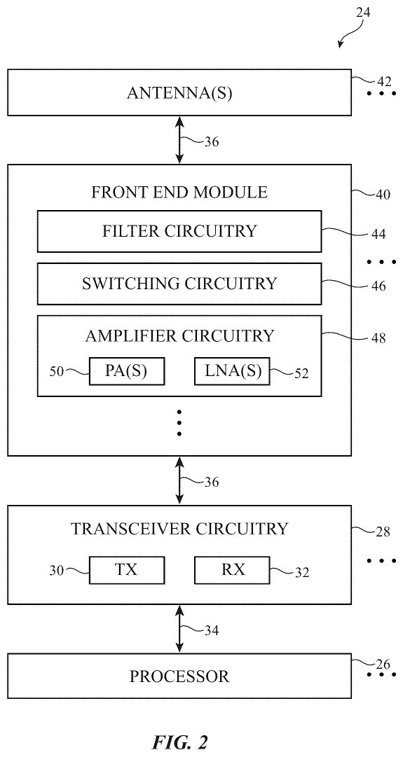

FIG. 2 is a diagram showing illustrative components within wireless circuitry 24. As shown in FIG. 2, wireless circuitry 24 may include a processor such as processor 26, radio-frequency (RF) transceiver circuitry such as radio-frequency transceiver 28, radio-frequency front end circuitry such as radio-frequency front end module (FEM) 40, and antenna(s) 42. Processor 26 may be a baseband processor, application processor, general purpose processor, microprocessor, microcontroller, digital signal processor, host processor, application specific signal processing hardware, power management unit, or other type of processor. Processor 26 may be coupled to transceiver 28 over path 34. Transceiver 28 may be coupled to antenna 42 via radio-frequency transmission line path 36. Radio-frequency front end module 40 may be disposed on radio-frequency transmission line path 36 between transceiver 28 and antenna 42.

In the example of FIG. 2, wireless circuitry 24 is illustrated as including only a single processor 26, a single transceiver 28, a single front end module 40, and a single antenna 42 for the sake of clarity. In general, wireless circuitry 24 may include any desired number of processors 26, any desired number of transceivers 28, any desired number of front end modules 40, and any desired number of antennas 42. Each processor 26 may be coupled to one or more transceiver 28 over respective paths 34. Each transceiver 28 may include a transmitter circuit 30 configured to output uplink signals to antenna 42, may include a receiver circuit 32 configured to receive downlink signals from antenna 42, and may be coupled to one or more antennas 42 over respective radio-frequency transmission line paths 36. Each radio-frequency transmission line path 36 may have a respective front end module 40 disposed thereon. If desired, two or more front end modules 40 may be disposed on the same radio-frequency transmission line path 36. If desired, one or more of the radio-frequency transmission line paths 36 in wireless circuitry 24 may be implemented without any front end module disposed thereon.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards.

In performing wireless transmission, processor 26 may provide transmit signals (e.g., digital or baseband signals) to transceiver 28 over path 34. Transceiver 28 may further include circuitry for converting the transmit (baseband) signals received from processor 26 into corresponding radio-frequency signals. For example, transceiver circuitry 28 may include mixer circuitry for up-converting (or modulating) the transmit (baseband) signals to radio frequencies prior to transmission over antenna 42. The example of FIG. 2 in which processor 26 communicates with transceiver 28 is illustrative. In general, transceiver 28 may communicate with a baseband processor, an application processor, general purpose processor, a microcontroller, a microprocessor, or one or more processors within circuitry 18. Transceiver circuitry 28 may also include digital-to-analog converter (DAC) and/or analog-to-digital converter (ADC) circuitry for converting signals between digital and analog domains. Transceiver 28 may use transmitter (TX) 30 to transmit the radio-frequency signals over antenna 42 via radio-frequency transmission line path 36 and front end module 40. Antenna 42 may transmit the radio-frequency signals to external wireless equipment by radiating the radio-frequency signals into free space.

Front end module (FEM) 40 may include radio-frequency front end circuitry that operates on the radio-frequency signals conveyed (transmitted and/or received) over radio-frequency transmission line path 36. FEM 40 may, for example, include front end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifier circuits 50 and/or one or more low-noise amplifier circuits 52), impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front end module components may be mounted to a common (shared) substrate such as a rigid printed circuit board substrate or flexible printed circuit substrate. If desired, the various front end module components may also be integrated into a single integrated circuit chip. If desired, amplifier circuitry 48 and/or other components in front end 40 such as filter circuitry 44 may also be implemented as part of transceiver circuitry 28.

Filter circuitry 44, switching circuitry 46, amplifier circuitry 48, and other circuitry may be disposed along radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Transceiver 28 may be separate from front end module 40. For example, transceiver 28 may be formed on another substrate such as the main logic board of device 10, a rigid printed circuit board, or flexible printed circuit that is not a part of front end module 40. While control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, processor 26 and/or portions of transceiver 28 (e.g., a host processor on transceiver 28) may form a part of control circuitry 14. Control circuitry 14 (e.g., portions of control circuitry 14 formed on processor 26, portions of control circuitry 14 formed on transceiver 28, and/or portions of control circuitry 14 that are separate from wireless circuitry 24) may provide control signals (e.g., over one or more control paths in device 10) that control the operation of front end module 40.

Transceiver circuitry 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

As described above, front end module 40 may include one or more power amplifiers (PA) circuits 50 in the transmit (uplink) path. A power amplifier 50 (sometimes referred to as radio-frequency amplifier, transmit amplifier, or amplifier) may be configured to amplify a radio-frequency signal without changing the signal shape, format, or modulation. Amplifier 50 may, for example, be used to provide 10 dB of gain, 20 dB of gain, 10-20 dB of gain, less than 20 dB of gain, more than 20 dB of gain, or other suitable amounts of gain.

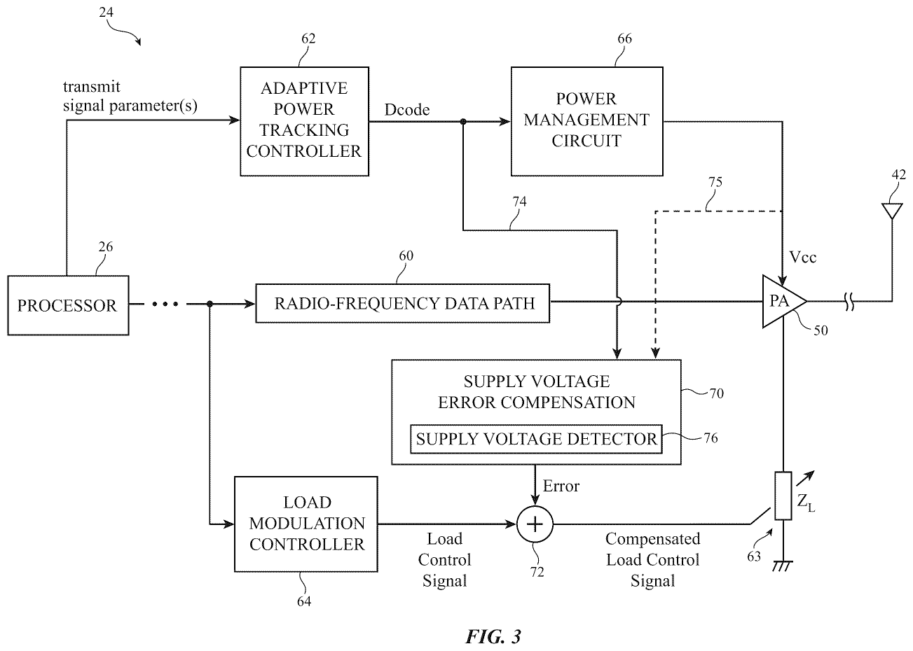

It can be challenging to design a satisfactory radio-frequency amplifier for an electronic device. FIG. 3 is a diagram of illustrative wireless circuitry 24 having a load modulated radio-frequency amplifier 50 configured to receive a radio-frequency input signal via a radio-frequency data path 60, a time-varying power supply voltage Vcc via a power tracking control circuit such as adaptive power tracking (APT) controller 62, and a load control signal via a load modulation control circuit such as load modulation controller 64. Radio-frequency data path 60 may receive a baseband signal from processor 26. Processor 26 may be considered part of wireless circuitry 24 or may be considered separate from wireless circuitry 24. Processor 26 may represent one or more processors such as a baseband processor, an application processor, a digital signal processor, a microcontroller, a microprocessor, a central processing unit (CPU), a programmable device, a combination of these circuits, and/or one or more processors within circuitry 18. Processor 26 may be configured to generated digital signals, which are sometimes referred to as baseband signals, digital signals, or transmit signals. As examples, the digital signals generated by processor 26 may include in-phase (I) and quadrature-phase (Q) signals, radius and phase signals, or other digitally-coded signals.

The radio-frequency (transmit) data path 60 can include one or more upconversion circuits (e.g., a radio-frequency mixer or modulator for upconverting signals from a baseband frequency range in the range of a couple hundred to a couple thousand Hz to radio frequencies in the range of hundreds of MHz, in the GHz range, or in the THz range), a digital predistortion circuit (e.g., a circuit for predistorting baseband signals prior to amplification at amplifier 50), one or more variable gain (digital) amplifiers, a data converter (e.g., a digital-to-analog conversion or “DAC” circuit, a radio-frequency DAC block, etc.), and/or other baseband/intermediate-frequency/radio-frequency transmitting circuit components. The signals conveyed through RF data path 60 can be provided to a data input (port) of amplifier 50. Radio-frequency amplifier 50 may have an output port that is coupled to antenna 42. Although not explicitly shown in FIG. 3, one or more additional radio-frequency front end components (e.g., filter, switching, tuning, or matching circuitry) can be coupled to input port and/or output port of amplifier 50.

As shown in FIG. 3, amplifier 50 may have a power supply terminal configured to receive a power supply voltage Vcc generated by a power management circuit such as power management circuit 66. Supply voltage Vcc that is received at the power supply terminal of radio-frequency amplifier 50 may be referred to as an amplifier power supply voltage. Power management circuit 66 may be coupled between adaptive power tracking controller 62 and the power supply terminal of amplifier 50. Adaptive power tracking controller 62 may be configured to dynamically adjust amplifier power supply voltage Vcc in response to a required output power level configured by processor 26. Adaptive power tracking controller 62 may receive and analyze a baseband (transmit) signal parameters such as required output power, signal crest factor, modulation type, signal bandwidth or the like from processor 26 and generate a corresponding power control digital code Decode. Power management circuit 66 may receive the power control digital code Dcode and output a corresponding power supply voltage Vcc depending on the value of Dcode. A higher Dcode value may result in a higher Vcc, whereas a lower Dcode value may result in the lower Vcc, or vice versa. Updates to the digital code Dcode an occur on a certain time raster basis such as a symbol time grid or a slot time grid. The power supply terminal of amplifier 50 that receives Vcc may sometimes be referred to and defined herein as a “control input” of amplifier 50, and power supply voltage Vcc output from power management circuit 66 can therefore sometimes be referred to as a “control signal” for amplifier 50. Adaptive power tracking controller 62 and power management circuit 66 can therefore sometimes be referred to collectively herein as a “control signal generator.”

Amplifier 50 may have an adjustable load component Z_{L}, configured to receive a load control signal generated from a load modulation control circuit such as load modulation controller 64 disposed along a load modulation path. Amplifier 50 having adjustable load component Z_{L}, is sometimes referred to and defined herein as a load modulated radio-frequency amplifier. Adjustable component Z_{L} of load modulated amplifier 50 can be tuned to provide different gain profiles with efficient transmit efficiency. The gain of load modulated amplifier 50 can be inversely proportional to the load value (e.g., a high Z_{L} value will increase the gain, whereas a low Z_{L} value will decrease the gain). Load component Z_{L} can be implemented as an adjustable capacitance, an adjustable resistance, an adjustable inductance, one or more passive electrical components, one or more active electrical components including transistor(s), some combination of these components, and/or other adjustable load element. Terminal 63 of the adjustable load component Z_{L} that receives the load control signal may sometimes also be referred to and defined herein as a “control input” of amplifier 50. Thus, the load control signal output from load modulation controller 64 can also therefore sometimes be referred to as a “control signal” for amplifier 50. Load modulation controller 64 can therefore sometimes be referred to as a “control signal generator.” Adaptive power tracking controller 62 and load modulation controller 64 can thus collectively be referred to as control signal generators.

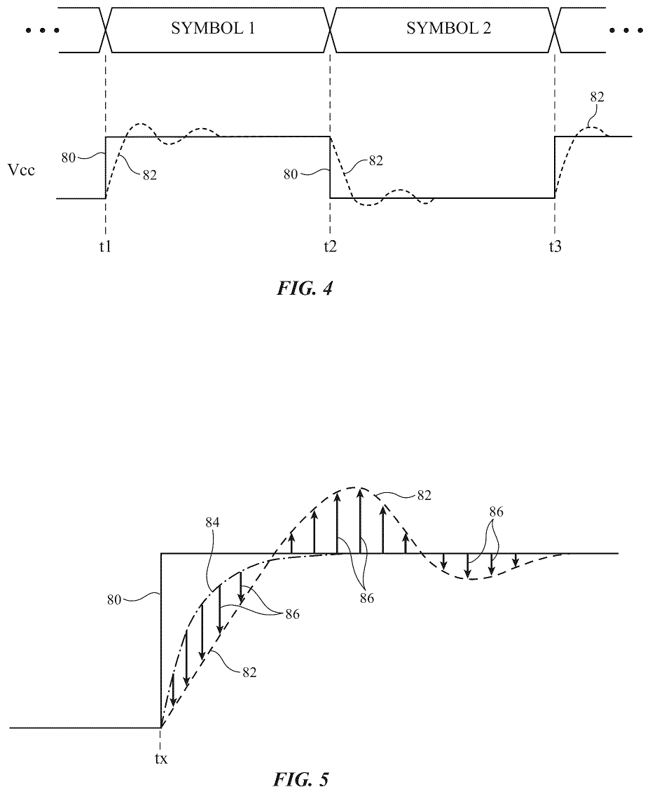

Adaptive power tracking controller 62 can be configured to toggle the amplifier power supply voltage Vcc on a per transmit symbol basis (see, e.g., FIG. 4). For example, adaptive power tracking controller 62 may receive the target antenna output power level output from processor 26 and output a corresponding digital code Dcode that aims to adjust Vcc to provide a maximum signal peak for each transmit symbol. As shown in the timing diagram of FIG. 4, the amplifier power supply voltage Vcc can change voltage levels (as directed by APT controller 62) from symbol to symbol or from slot to slot.

In the scenario illustrated in FIG. 4, Vcc can be adjusted to a first voltage level for transmitting a first symbol at time t1. At time t2, Vcc can be adjusted to a second voltage level different than the first voltage level for transmitting a second symbol. At time t3, Vcc can be adjusted to yet another voltage level for transmitting a subsequent symbol. Different symbols can require a different amplifier power level. Here, the APT controller 62 can direct Vcc to change voltage levels at every symbol transition. For example, a new symbol can be transmitted once every 20 μs (microseconds), once every 10-20 μs, once every 20-30 μs, once every 30-40 μs, once every 40-50 μs, or at other intervals depending on the data transmission rate of the wireless circuitry. Changing Vcc levels every symbol but keeping the voltage level constant/fixed throughout each symbol period in this way is sometimes referred to and defined herein as a “piecewise constant” power supply voltage modulation scheme. This results from the fact that the digital codes output from APT controller 62 are also piecewise constant. Such type of piecewise constant control scheme is less complex and less costly than conventional envelope tracking (ET) techniques where the power supply voltage of the radio-frequency power amplifier is continuously adjusted such that the gain of the power amplifier remains constant over varying signal amplitudes, sometimes referred to as iso-gain operation.

Waveform 80 may represent the ideal Vcc signal waveform with sharp transitions. In practice, however, the actual Vcc signal waveform 82 can exhibit non-ideal transient behavior with ringing that gradually settles over a period of time. Waveform 82 shows how the transient behavior can exhibit overshoot and undershoot voltage levels in comparison to the ideal square waveform 80. To avoid throughput degradation, such ringing or voltage transients will need to settle within a threshold period of time that will only become shorter as wireless/radio technology advances. If care is not taken, the slow settling time of waveform 82 can thus degrade the radio-frequency output signal and degrade data transmission throughput.

In accordance with an embodiment, a means for correcting or compensating the instantaneous voltage overshoot and undershoot in the non-ideal transient waveform 82 is provided. Referring back to FIG. 3, wireless circuitry 24 may further include power supply voltage compensation circuitry such as supply voltage error compensation circuitry 70. As shown in FIG. 3, supply voltage error compensation circuitry 70 may have an input configured to receive digital code Dcode from adaptive power tracking controller 62 and may include a means for sensing or detecting a voltage level of power supply voltage Vcc that is being received at amplifier 50 such as supply voltage detector 76. As an example, supply voltage detector 76 can detect the voltage level of Vcc that is being received amplifier 50 by directly routing over via a local sensing line 75. This is illustrative. Other ways of detecting, estimating, or predicting the voltage level of local amplifier power supply voltage Vcc can be employed by supply voltage error compensation circuitry 70.

The operational concept of supply voltage error compensation circuitry 70 is best understood in conjunction with the timing diagram of FIG. 5. Waveform 80 may represent the ideal Vcc signal waveform with sharp transitions. Waveform 80 is sometimes referred to and defined herein as a reference power supply waveform or reference power supply signal. Waveform 82 may represent the transient behavior showing ringing with voltage overshoot and undershoot of the power supply voltage Vcc that actually arrives at the power supply terminal of amplifier 50. Forcing waveform 82 to converge to the ideal/reference waveform 80 may not be practical. In some embodiments, supply voltage error compensation circuitry 70 may filter the reference waveform 80 to produce a corresponding filtered power supply waveform 84. Filtered waveform 84 is sometimes referred to and defined herein as a target power supply waveform or target power supply signal. For example, target waveform 84 may be a low-pass filtered version of reference waveform 80. It is recognized herein that having transient waveform 82 converge upon the filtered target waveform 84 may be sufficient.

Supply voltage error compensation circuitry 70 can generate reference Vcc waveform 80 based on the received digital code Dcode and can subsequently generate filtered/target Vcc waveform 82 based on the reference Vcc waveform 80. The supply voltage detector 76 in supply voltage error compensation circuitry 70 can be configured to obtain transient waveform 82, which represents the actual Vcc waveform that is received locally at the power supply terminal of amplifier 50. Supply voltage error compensation circuitry 70 can then generate an error signal based on a difference between waveforms 82 and 84 (see, e.g., FIG. 5 error voltages 86 reflecting voltage deltas between the instantaneous actual Vcc and the instantaneous target Vcc). Such error signal generated by supply voltage error compensation circuitry 70 can be combined, at signal combiner 72 (e.g., a voltage summing circuit), with the load control signal output from load modulation controller 64 to produce a corresponding compensated load control signal. The adjustable load component Z_{L} of load modulated amplifier 50 can be directly tuned by the compensated load control signal. Wireless circuitry 24 configured and operated in this way is technically advantageous and beneficial by allowing for slower settling time in waveform 82, which relaxes the design of power management circuit 66, without transmit throughput degradation.

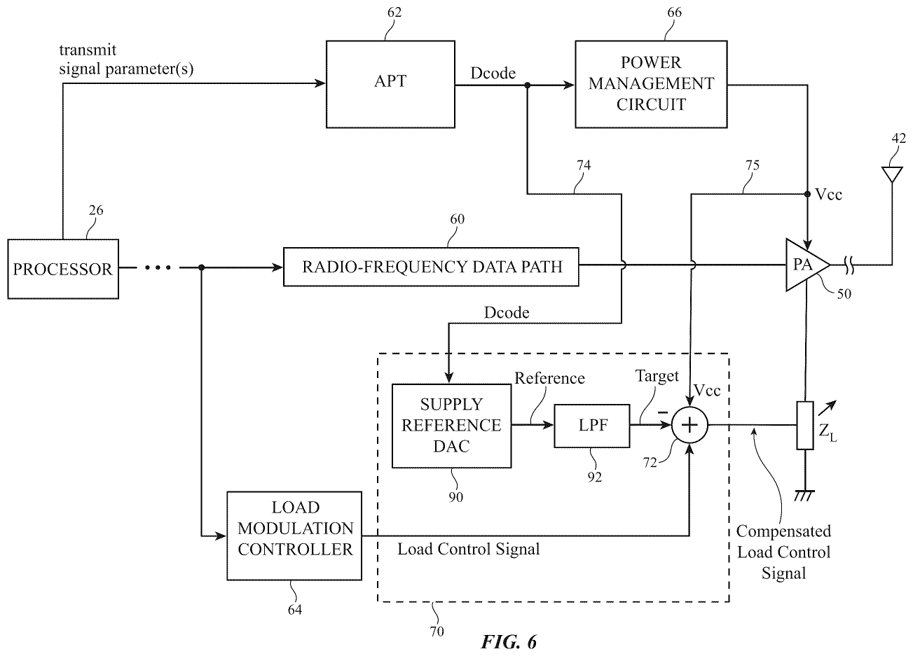

FIG. 6 shows one illustrative configuration of supply voltage error compensation circuitry 70. As shown in FIG. 6, supply voltage error compensation circuitry 70 may include a reference signal generator (or supply reference generator) such as a supply reference digital-to-analog converter (DAC) 90, a filtering component such as filter 92, and a signal combiner such as combiner 72. Supply reference DAC 90 may receive digital code Dcode from the APT controller 62 via path 74 and may generate a corresponding reference supply voltage waveform. Filter 92 may, as an example, be a low pass filter or other types of filtering component. Filter 92 may receive the reference supply voltage waveform from DAC 90 and filter the reference supply voltage waveform to generate a corresponding target supply voltage waveform.

Combiner 72 may have a first input configured to receive the target supply voltage waveform, a second input configured to receive the actual supply voltage waveform received at amplifier 50 via sensing path 75 (sometimes referred to as the Vcc waveform), and a third input configured to receive a load control signal from load modulation controller 64. Sensing path 75 serves as supply voltage detector 76 that physically routes over the Vcc waveform with overshoots and undershoots. Combiner 72 may be configured to generate an error signal by computing a difference between the target supply voltage waveform and the Vcc waveform. Combiner 72 may further combine the error signal with the load control signal being received at the third input to generate the compensated load control signal (e.g., the error signal can be applied or added to load control signal to produce the compensated load control signal). The compensated load control signal tunes the adjustable load component Z_{L} of load modulated amplifier 50.

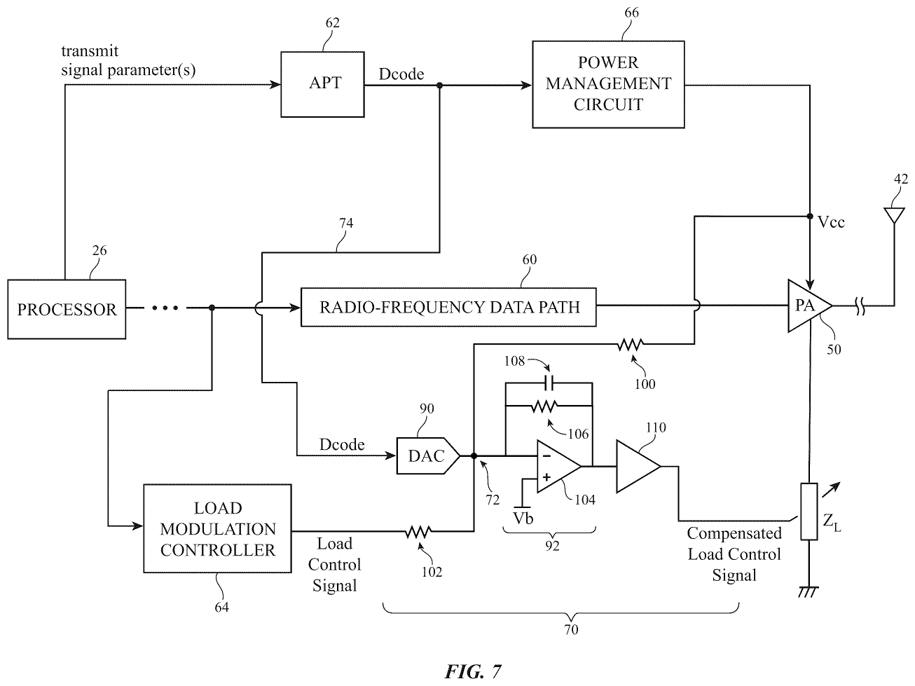

FIG. 7 shows an exemplary implementation of supply voltage error compensation circuitry 70 of the type described in connection with FIG. 6. As shown in FIG. 7, supply reference DAC 90 may receive digital code Dcode from the APT controller 62 via path 74 and may generate a corresponding reference supply voltage waveform. Low-pass filter 92 may be implemented using a resistor 106 and a capacitor 108 coupled across an operational amplifier 104. Resistor 106 may have a first terminal coupled to a first (negative) input port of operational amplifier 104 and may have a second terminal coupled to an output port of operational amplifier 104. Capacitor 108 may have a first terminal coupled to the first (negative) input port of operational amplifier 104 and may have a second terminal coupled to the output port of operational amplifier 104. Operational amplifier 104 may have a second (positive) input port configured to receive a bias voltage Vb.

The supply reference DAC 90 may have an output port coupled to node 72. The first (negative) input port of operational amplifier 104 may be coupled to node 72. Node 72 may be configured to receive the amplifier power supply Vcc waveform via resistor 100. Resistor 100 (and the associated conductive path (wire) connecting the power supply terminal of load modulated amplifier 50 to node 72 may provide a physical connection or sensing path for supply voltage detector 76. Load modulation controller 64 may have an output port also coupled to node 72 via resistor 102. Configured in this way, node 72 serves as a common (shared) point at which the reference supply voltage waveform, the target (filtered) supply voltage waveform, the actual Vcc waveform, and the load control signal are combined as described in connection with FIG. 6 (e.g., the reference supply voltage waveform can be filtered to produce the target supply voltage waveform; an error signal can be computed based on the difference between the target supply voltage waveform and the actual Vcc waveform; and the error signal can be applied to the load control signal to produce a corresponding compensated load control signal). The compensated load control signal can be generated at the output port of operational amplifier 104 and can be driven using buffer 110 onto control terminal 63 of adjustable load component Z_{L}.

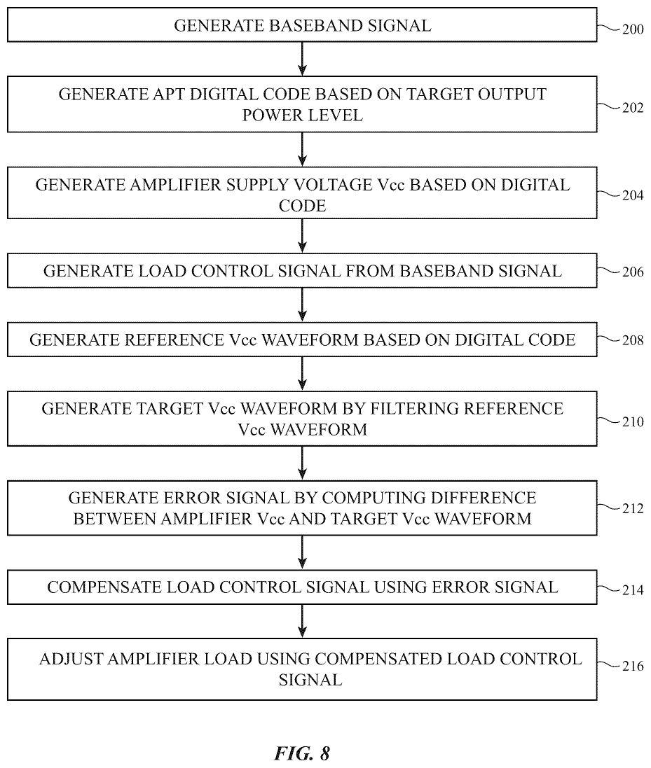

FIG. 8 is a flow chart of illustrative steps for operating wireless circuitry 24 of the type described in connection with at least FIGS. 3, 6, and 7 in accordance with some embodiments. During the operations of block 200, processor 26 may generate a baseband signal. The baseband signal can be provided to a data input of load modulated amplifier 50 via radio-frequency data path 60 and to an input of load modulation controller 64 in the load modulation path.

During the operations of block 202, adaptive power tracking controller 62 may generate an APT digital code Dcode based on a target antenna output power control parameter, which may define to what power level the baseband signal shall be converted or transmitted. The APT digital code Dcode can be provided to an input of power management circuit 66 and to an input of supply voltage error compensation circuitry 70 via path 74.

During the operations of block 204, power management circuit 66 may generate amplifier power supply voltage Vcc based on the received digital code Dcode. Amplifier power supply voltage Vcc generated in this way using APT controller 62 and power management circuit 66 may ideally have a piecewise constant transient waveform as shown in FIG. 4. Amplifier power supply voltage Vcc waveform that is received locally at the power supply terminal of amplifier 50 can exhibit relatively slow settling times with some amount of rippling (e.g., with voltage overshoot and undershoot as shown in FIGS. 4 and 5).

During the operations of block 206, load modulation controller 64 may generate a load control signal from the received baseband signal. The example of FIG. 8 in which block 206 is shown as occurring after block 204 is illustrative. In practice, the operations of block 206 can occur in parallel with or before the operations of block 202 and/or 204.

During the operations of block 208, supply voltage error compensation circuitry 70 can generate a reference supply voltage waveform based on the received digital code. The reference supply voltage waveform may have an ideal behavior with sharp transitions (see, e.g., waveform 80 in FIGS. 4 and 5).

During the operations of block 210, supply voltage error compensation circuitry 70 may generate a target supply voltage waveform by filtering the reference supply voltage waveform. Circuitry 70 may employ a filter such as low-pass filter 92 in FIG. 6 or FIG. 7 to generate the target supply voltage waveform. The target supply voltage waveform may sometimes be referred to as the filtered supply voltage waveform. The target supply voltage waveform may have a smoother transition than the reference/ideal supply voltage waveform (see, e.g., waveform 84 in FIG. 5).

During the operations of block 212, supply voltage error compensation circuitry 70 may generate an error signal by computing a difference between the target supply voltage waveform and amplifier supply voltage Vcc (e.g., the actual Vcc waveform received by amplifier 50 and as routed over by a physical voltage sensing path). The example of FIG. 8 in which blocks 208, 210, and 212 are shown as occurring after block 206 is illustrative. If desired, the operations of blocks 208, 210, and 212 can optionally occur in parallel with or before block 206 and/or block 204.

During the operations of block 214, supply voltage error compensation circuitry 70 may compensate the load control signal using the error signal obtained from block 212. For instance, the error signal can be applied to or additively combined with the load control signal generated from block 206. During the operations of block 216, the adjustable load component Z_{L} of load modulated amplifier 50 may be tuned using the compensated load control signal. Operated in this way, the wireless (transmit) circuitry 24 is technically improved by allowing for slower supply voltage settling times at the output of power management circuit 66 without data throughput degradation.

The operations of FIG. 8 are merely illustrative. In some embodiments, one or more of the described operations may be modified, replaced, or omitted. In some embodiments, one or more of the described operations may be performed in parallel. In some embodiments, additional processes may be added or inserted between the described operations. If desired, the order of certain operations may be reversed or altered and/or the timing of the described operations may be adjusted so that they occur at slightly different times. In some embodiments, the described operations may be distributed in a larger system.

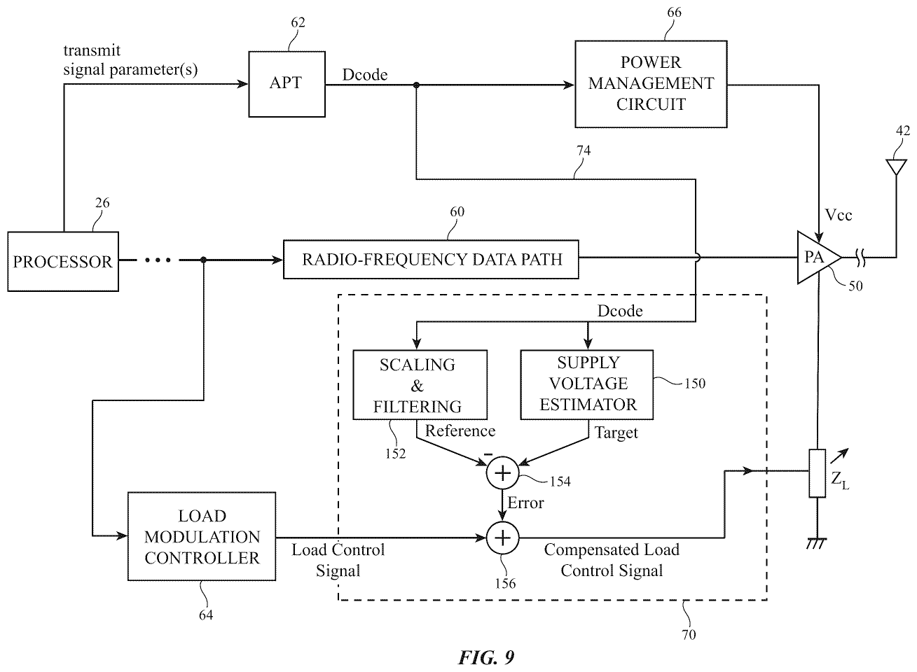

The embodiment of FIG. 6 in which supply voltage error compensation circuitry 70 senses the amplifier power supply voltage Vcc via a direct/physical sensing path (e.g., sensing path 75) is exemplary. FIG. 9 shows another embodiment of supply voltage error compensation circuitry 70 that includes a scaling and filtering circuit such as scaling and filtering block 152 and a supply voltage estimation circuit such as supply voltage estimation block 150. As shown in FIG. 9, supply voltage estimation block 150 may have an input configured to receive digital code Dcode from the APT controller 62 and may have an output on which an estimated supply voltage waveform is generated. Supply voltage estimation block 150 may, for example, be implemented as part of a digital signal processor or other processing or control circuitry that generates the target supply voltage waveform based on a digital model of power management circuit 66 that can simulate/estimate the non-ideal transient behavior with rippling (see, e.g., waveform 82 in FIGS. 4 and 5). Supply voltage estimation block 150 can therefore represent a model-based supply voltage detector 76 of FIG. 3.

Scaling and filtering block 152 may have an input configured to receive digital code Dcode from the APT controller 62 and may have an output on which a reference supply voltage waveform is generated. Assuming supply voltage estimation block 150 outputs a digital signal, the reference supply voltage waveform should also be encoded as a digital signal. Thus, scaling and filtering block 152 can be implemented as part of a digital signal processor or other processing or control circuitry configured to take the received Dcode and scale it to the same level as the digital model associated with block 150 and then apply (digital) low-pass filtering. The output of scaling and filtering block 152 can therefore sometimes be referred to herein as a reference power supply (digital) signal, whereas the output of supply voltage estimation block 150 can sometimes be referred to as a target/filtered power supply (digital) signal. Block 152 is therefore sometimes referred to as a reference signal generator.

Supply voltage error compensation circuitry 70 can further include a digital combiner component 154 for combining the reference power supply digital signal with the estimated power supply digital signal to generate a corresponding error signal based on a difference between the reference power supply digital signal and the target power supply digital signal. Supply voltage error compensation circuitry 70 can further include a digital combiner component 156 for combining the load control signal output from load modulation controller 64 with the error signal to generate a corresponding compensated load control signal. The adjustable load component Z_{L} of load modulated amplifier 50 can be directly tuned by the compensated load control signal. Wireless circuitry 24 configured and operated in this way is technically advantageous and beneficial by allowing for slower settling time in the supply voltage Vcc being received at amplifier 50, which relaxes the design of the power supply modulation path without transmit throughput degradation.

The methods and operations described above in connection with FIGS. 1-9 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The foregoing is merely illustrative and various modifications can be made to the described embodiments. The foregoing embodiments may be implemented individually or in any combination.

What is claimed is:

1. Wireless circuitry comprising:
a radio-frequency amplifier configured to receive a radio-frequency signal generated from a baseband signal and to receive a power supply voltage;
a load modulation circuit configured to generate a load control signal from the baseband signal; and
supply voltage error compensation circuitry configured to generate an error signal that is applied to the load control signal to produce a compensated load control signal, wherein an adjustable load component of the radio-frequency amplifier is tuned by the compensated load control signal.

2. The wireless circuitry of claim 1, further comprising:
an adaptive power tracking control circuit configured to generate a digital code based on a target output power level; and
a power management circuit configured to generate the power supply voltage for the radio-frequency amplifier based on the digital code.

3. The wireless circuitry of claim 2, wherein the digital code generated by the adaptive power tracking control circuit is piecewise constant.

4. The wireless circuitry of claim 2, wherein the supply voltage error compensation circuitry comprises:
a reference signal generator configured to receive the digital code and to generate a reference supply voltage waveform.

5. The wireless circuitry of claim 4, wherein the reference signal generator comprises a supply reference digital-to-analog converter (DAC) configured to generate an analog reference supply voltage waveform.

6. The wireless circuitry of claim 4, wherein the supply voltage error compensation circuitry further comprises:
a low-pass filter configured to receive the reference supply voltage waveform and to generate a corresponding target supply voltage waveform.

7. The wireless circuitry of claim 6, wherein the supply voltage error compensation circuitry further comprises:
a supply voltage detector configured to sense the power supply voltage received at the radio-frequency amplifier, wherein the supply voltage error compensation circuitry is configured to generate the error signal based on a difference between the sensed power supply voltage and the target supply voltage waveform.

8. The wireless circuitry of claim 2, wherein the supply voltage error compensation circuitry comprises:
a supply voltage estimation block configured to receive the digital code and to generate an estimated power supply signal based on a digital model associated with the power management circuit.

9. The wireless circuitry of claim 8, wherein the supply voltage error compensation circuitry further comprises:
a scaling and filtering block configured to receive the digital code and to generate a reference power supply signal by scaling and filtering the received digital code.

10. The wireless circuitry of claim 9, wherein the supply voltage error compensation circuitry further comprises:
a combiner configured to generate the error signal based on a difference between the estimated power supply signal and the reference power supply signal.

11. A method of operating wireless circuitry comprising:
with a radio-frequency amplifier, receiving a radio-frequency signal generated from a baseband signal and receiving a power supply voltage;
with a load modulation circuit, generating a load control signal from the baseband signal;
with supply voltage error compensation circuitry, generating an error signal and combining the error signal with the load control signal to produce a compensated load control signal; and
tuning an adjustable load component of the radio-frequency amplifier with the compensated load control signal.

12. The method of claim 11, further comprising:
with an adaptive power tracking controller, generating a digital code based on a target antenna output power level; and
with a power management circuit, receiving the digital code and driving the power supply voltage that is received at the radio-frequency amplifier.

13. The method of claim 12, further comprising:
generating a reference power supply signal based on the digital code; and
generating a target power supply signal by filtering the reference power supply signal.

14. The method of claim 13, further comprising:
sensing the power supply voltage, wherein generating the error signal comprises generating the error signal by computing a difference between the sensed power supply voltage and the target power supply signal.

15. The method of claim 13, further comprising:
estimating the power supply voltage based on a digital model of the power management circuit, wherein generating the error signal comprises generating the error signal by computing a difference between the estimated power supply voltage and the target power supply signal.

16. The method of claim 12, further comprising:
with the power management circuit, driving the power supply voltage to a first fixed voltage level while transmitting a first symbol in the baseband signal; and
with the power management circuit, driving the power supply voltage to a second fixed voltage level different than the first fixed voltage level while transmitting a second symbol in the baseband signal.

17. Circuitry comprising:
an amplifier having a data input, a first control input, and a second control input;
a first control signal generator configured to output a first control signal to the first control input of the amplifier;
a second control signal generator configured to output a second control signal; and
error compensation circuitry configured to
sense or estimate the first control signal received at the first control input of the amplifier, and
generate an error signal for compensating the second control signal, wherein the compensated second control signal is provided to the second control input of the amplifier.

18. The circuitry of claim 17, wherein the first control signal generator comprises:
a power tracking controller configured to output a digital code; and
a power management circuit configured to output the first control signal based on the digital code.

19. The circuitry of claim 18, wherein the amplifier further comprises an adjustable load that is tuned by the compensated second control signal.

20. The circuitry of claim 18, wherein the error compensation circuitry comprises:
a reference signal generator configured to generate a reference signal based on the digital code; and
a filter configured to generate a target signal based on the reference signal, wherein the error signal is computed based on a difference between the target signal and the sensed or estimated version of the first control signal.
